(19) United States
(12) Patent Application Publication
(10) Pub. No.: US 2009/0060687 A1
(43) Pub. Date: Mar. 5, 2009

(54) TRANSFER CHAMBER WITH ROLLING DIAPHRAGM

(76) Inventor: JOHN M. WHITE, Hayward, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/846,389

(22) Filed: Aug. 28, 2007

(51) Int. Cl. H01L 21/677; G06F 19/00

(52) U.S. Cl. 414/217; 700/245

(57) ABSTRACT

Embodiments of the invention include a vacuum transfer chamber having one rolling or more rolling diaphragm providing a seal between a robot disposed in the transfer chamber and the transfer chamber and a method for using a substrate transfer chamber having the same.

### BACKGROUND OF THE INVENTION

1. Field of the Invention

Embodiments of the invention generally relate to a vacuum transfer chamber having a rolling diaphragm.

2. Description of the Related Art

Two rapidly evolving technology areas are thin film transistors and photovoltaic devices. Thin film transistors (TFT) formed by flat panel technology are commonly used for active matrix displays such as computer and television monitors, cell phone displays, personal digital assistants (PDAs), and an increasing number of other devices. Generally, flat panels comprise two glass plates having a layer of liquid crystal materials sandwiched therebetween. At least one of the glass plates includes one conductive film disposed thereon that is coupled to a power source. Power, supplied to the conductive film from the power source, changes the orientation of the crystal material, creating a pattern display.

Photovoltaic devices (PV) or solar cells are devices which convert sunlight into direct current (DC) electrical power. PV or solar cells typically have one or more p-n junctions formed on a panel. Each junction comprises two different regions within a semiconductor material where one side is denoted as the p-type region and the other as the n-type region. When the p-n junction of the PV cell is exposed to sunlight (consisting of energy from photons), the sunlight is directly converted to electricity through the PV effect. In general, a high quality silicon-based material is desired to produce high efficiency junction devices (i.e., high power output per unit area). Amorphous silicon (a-Si) film has been widely used as the silicon-based panel material in PV solar cells due to its low cost to manufacture in conventional low temperature plasma enhanced chemical vapor deposition (PECVD) processes.

With the marketplace's acceptance of flat panel technology and desire for more efficient PV devices to offset spiraling energy costs, the demand for larger panels, increased production rates and lower manufacturing costs have driven equipment manufacturers to develop new systems that accommodate larger area substrates for flat panel display and PV device fabricators. Current substrate processing equipment, which typically includes a vacuum transfer chamber surrounded by a load lock chamber and a plurality of vacuum processing chambers, is generally configured to accommodate substrates slightly greater than about two square meters. Processing equipment configured to accommodate larger substrate sizes is envisioned in the immediate future.

Equipment to fabricate such large substrates represents a substantial investment to fabricators. Conventional systems require large and expensive hardware. To enhance there the return on this investment, high substrate throughput is very desirable. One processing strategy to provide high substrate throughput is to utilized load lock chambers having stacked substrate transfer slots. Stacking the substrate transfer slots requires increasing the vertical size of the load lock chamber. Correspondingly, the use of such large load lock chambers has required transfer chamber robots to have greater z-axis (i.e., vertical) motion in order to reach the widely spaced upper and lower transfer slots.

Conventional robots disposed in a transfer chamber typically use lip seals and/or bellows to maintain a vacuum seal between the robot and transfer chamber, while facilitating the z-axis motion of the robot. Each of these seal have design limitations that are more pronounced in larger processing systems.

For example, lip seals require precision shaft and groove dimensioning, which is more difficult to maintain at large diameters. Furthermore, precision motion mechanisms are required so that alignment and seal integrity are maintained over the complete range of robot motion. Such precision components are very costly to manufacture. Moreover, lip seals in long stroke applications are prone to particle generation due to increased seal wear, which also shortens the service life of the seal.

Bellows are also costly to manufacture, particularly at the large diameters required for use in large area substrate processing equipment. Additionally, bellows suitable for use as a pressure barrier are typically not designed to accommodate an extended range of motion, which may make the bellow suspect for failure.

Thus, there is a need for an improved vacuum seal for use between a robot and vacuum transfer chamber that contributes to robust processing of larger area substrates.

### SUMMARY OF THE INVENTION

Embodiments of the invention include a vacuum transfer chamber having at least one rolling diaphragm providing a seal between a robot and a transfer chamber, and a method for using the same. In one embodiment, an apparatus for transfer of large area substrates under vacuum is provided that includes a vacuum chamber body, a lift mechanism, a robot and one or more rolling diaphragms. The robot is substantially disposed in an interior volume of the chamber body and coupled to the lift mechanism. The lift mechanism selectively controls the elevation of the robot within the interior volume. The one or more rolling diaphragms provide a seal between the robot and a bottom of the chamber body.

In another embodiment, an apparatus for transfer of large area substrates under vacuum is provided that includes a chamber body and a robot substantially disposed in an interior volume of the chamber body and coupled to a lift mechanism. The lift mechanism selectively controls the elevation of the robot within the interior volume. A first rolling diaphragm and a second rolling diaphragm are arranged in series and sealed at one end by a spacer. The spacer has a passage formed therethrough that communicates with an interstitial volume defined between the diaphragms. The passage through the spacer terminates in a port configured to accept a fitting for coupling to a vacuum source.

A method for transferring a large area substrate is also provided. In one embodiment, the method includes providing a transfer chamber having a robot disposed therein, the transfer chamber coupled to a load lock chamber and at least one processing chamber, the robot having an elevation selectable by a lift mechanism, the robot sealed to the transfer chamber by one or more rolling diaphragms, robotically transferring a substrate from at least one of the processing chamber or load lock chamber to the transfer chamber, adjusting the elevation of the of the substrate within the transfer chamber in a manner that causes a first end of the rolling diaphragm to move relative to a second end, and robotically transferring the substrate from the transfer chamber to at least one of the processing chamber or load lock chamber.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a plan view of an illustrative cluster tool having one embodiment of a vacuum transfer chamber of the present invention;

FIG. 2 is a partial sectional view of the vacuum transfer chamber taken along section line 2-2 of FIG. 1 having a rolling diaphragm proving a seal between a robot and the vacuum transfer chamber, the robot shown in a lowered position;

FIG. 3 is a partial sectional view of the rolling diaphragm of FIG. 2;

FIG. 4 is a partial sectional view of the vacuum transfer chamber having a rolling diaphragm assembly proving a seal between a robot and a vacuum transfer chamber;

FIG. 5 is a partial sectional view of a spacer; and

FIG. 6 is a partial sectional view of the vacuum transfer chamber of FIG. 2 illustrating the robot in a raised position.

To facilitate understanding, identical reference numerals have been used, wherever possible, to designate identical elements that are common to the figures. It is contemplated that elements of one embodiment may be advantageously utilized in other embodiments without further recitation.

### DETAILED DESCRIPTION

A transfer chamber having at least one rolling diaphragm disposed between a chamber body and robot is provided. Although specific embodiments of transfer chambers are provided below with reference to a large area substrate transfer chamber of a configuration available from AKT, Inc., a division of Applied Materials, Inc., of Santa Clara, Calif., it is contemplated that the inventive features and methods may be adapted for use in other transfer chambers, including those from other manufacturers. It is also contemplated that the inventive features and methods may be adapted for use with equipment suitable for processing smaller area substrates.

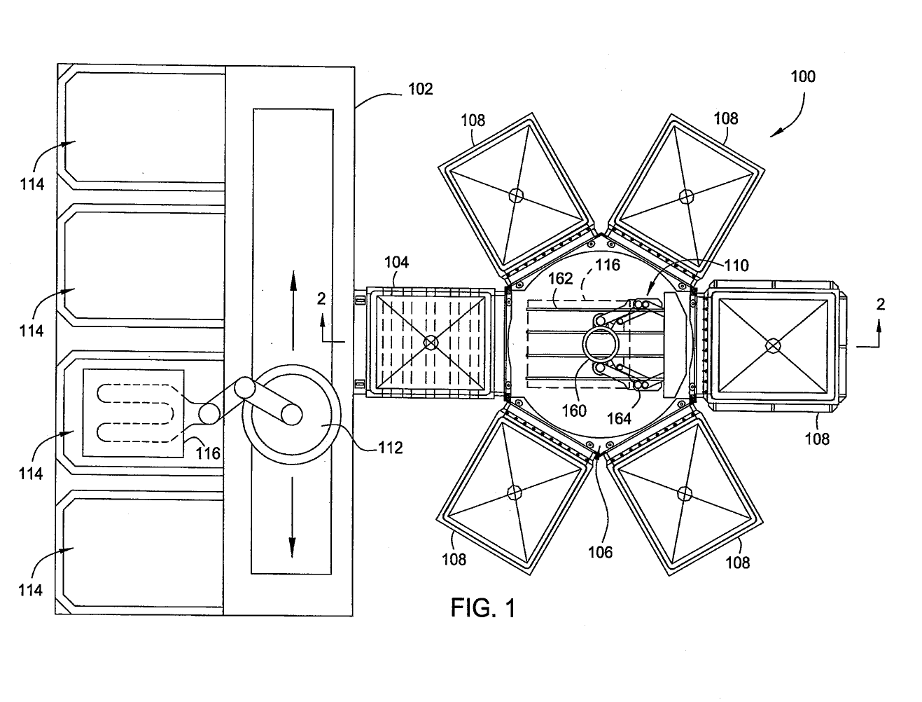

FIG. 1 is a plan view of an illustrative processing system 100, such as a linear or cluster tool, having one embodiment of a vacuum transfer chamber 106, one or more load lock chambers 104 and a plurality of processing chambers 108. A factory interface 102 coupled by the load lock chamber 104 to the transfer chamber 106 and includes a plurality of substrate storage cassettes 114 and an atmospheric robot 112. The atmospheric robot 112 facilitates transfer of substrates 116 between the cassettes 114 and the load lock chamber 104.

The substrate processing chambers 108 are coupled to the transfer chamber 106. The substrate processing chambers 108 may be configured to perform at least one of a chemical vapor deposition process, a physical vapor deposition process, an etch process or other large area substrate manufacturing process suitable for fabricating a flat panel display, solar cell or other device. Generally, large area substrates have a plan area of at least 1 square meter, and may be comprised of a glass or polymer sheet.

The load lock chamber 104 generally includes at least one environmentally-isolatable cavity having one or more substrate storage slots defined therein. In some embodiments, a plurality of environmentally-isolatable cavities may be provided, each having one or more substrate storage slots defined therein. The load lock chamber 104 is operated to transfer substrates 116 between an ambient or atmospheric environment of the factory interface 102 and the vacuum environment maintained in the transfer chamber 106.

Exemplary load lock chambers are described in U.S. patent application Ser. No. 11/332,781, filed Jan. 13, 2006, U.S. patent application Ser. No. 10/832,795, filed Apr. 26, 2004, U.S. patent application Ser. No. 09/663,862, filed Sep. 15, 2000, U.S. patent application Ser. No. 10/842,079, filed May 10, 2004, and U.S. patent application Ser. No. 11/421,793, filed Jun. 2, 2006, and U.S. patent application Ser. No. 11/782,290 filed Jul. 24, 2007, all of which are incorporated by reference in there entireties. Other suitable load lock chambers are available from AKT, Inc., a division of Applied Materials, Inc., of Santa Clara, Calif., among other manufactures.

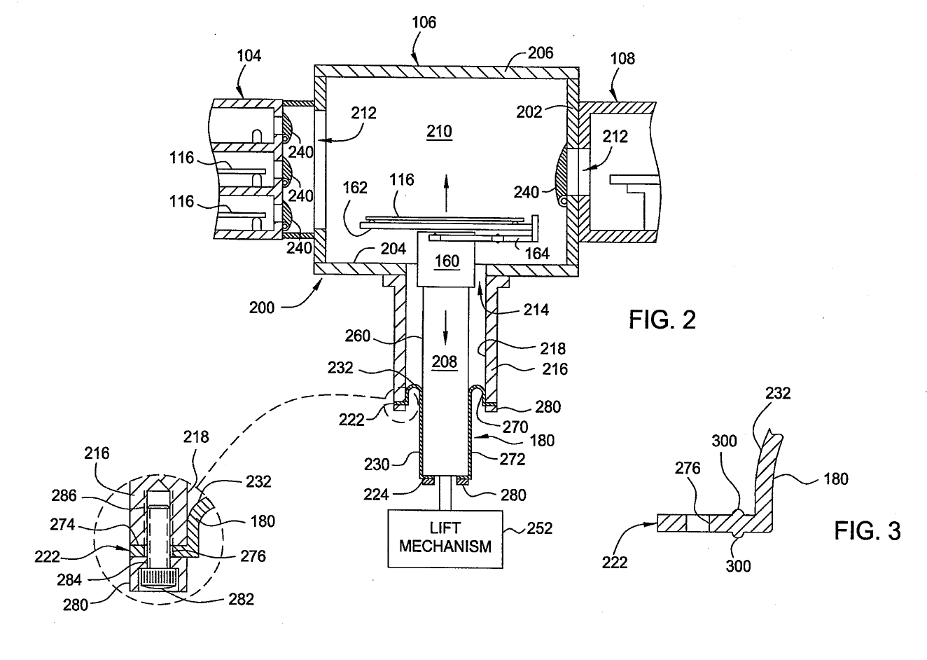

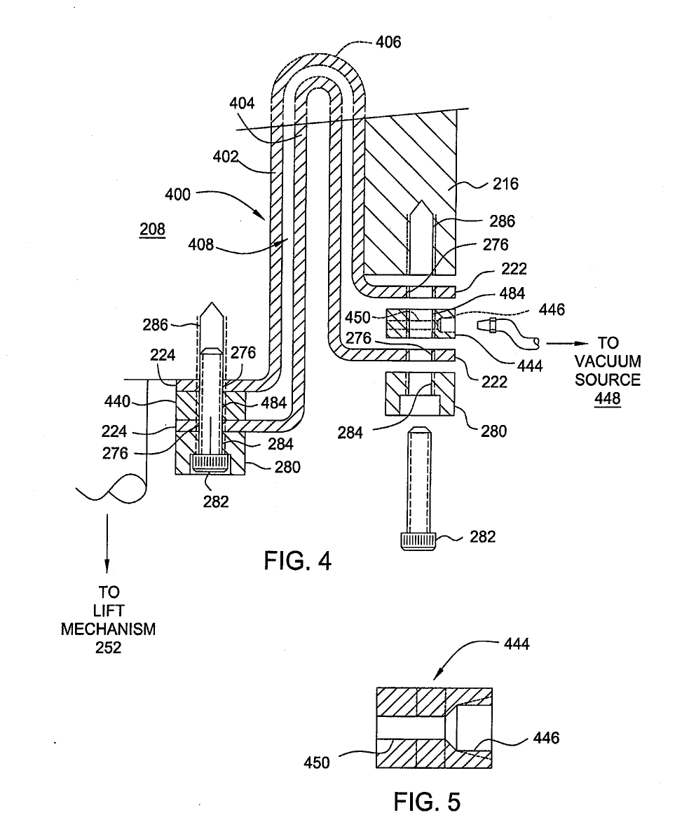

A vacuum robot 110 is disposed in the transfer chamber 106 to facilitate transfer of a substrate 116 between the load lock chamber 104 and the processing chambers 108. The vacuum robot 110 may be any robot suitable for transferring substrates under vacuum conditions. In the embodiment depicted in FIG. 1, the vacuum robot 110 is a polar or frog-leg robot that generally includes a robot base 160 which houses one or more motors (not shown) utilized to control the position of an end effector 162. The end effector 162 is coupled to the base 160 by a linkage 164. The vacuum robot 110 is sealed to the transfer chamber 104 by one or more rolling diaphragms, shown as rolling diaphragm 180 in FIGS. 2-3 and 6 and as rolling diaphragms 402, 404 in FIG. 4 below. The one or more rolling diaphragms facilitate control of the elevation of the end effector 162 and substrate 116 disposed thereon while preventing vacuum leakage from the chamber 106 as the robot 110 moves vertically. In one embodiment, the end effector 162 of the vacuum robot 110 has a range of vertical motion of at least 500 mm.

FIG. 2 depicts a partial sectional view of the transfer chamber 106 taken along section lines 2-2 of FIG. 1. The transfer chamber 106 has a chamber body 200 fabricated from a rigid material such as aluminum. The chamber body 200 generally includes a plurality of sidewalls 202, a chamber bottom 204 and a lid 206. The lid 206 may be removed to allow access to an interior volume 210 of the chamber body 200.

Two or more of the sidewalls 202 of the transfer chamber 106 include substrate access ports 212. The ports 212 are selectively seals by doors 240. In the embodiment depicted in FIG. 2, two substrate access ports 212 are shown in cross section, wherein a first of the substrate access ports 212 facilitates transfer of the large substrate to and from the load lock chamber 104, while a second of the substrate access ports 212 facilitates transfer of the large substrate to and from one of the processing chambers 108.

The bottom 204 of the chamber body 200 has an aperture 214 through which the vacuum robot 110 is supported. In the embodiment depicted in FIG. 2, an extension 216 is coupled to the bottom 204 of the transfer chamber 106. The extension 216 may be an integral part of the chamber body 200, or be a separate component sealing coupled thereto, for example by a continuous weld. Alternatively, the extension 216 may be fastened or clamped to the chamber body 200 in a manner that compresses an o-ring or other seal (not shown) that prevents leakage between the transfer chamber 106 and the extension 216. As utilized herein, the extension 210 is to be considered part of the chamber body 200.

The elevation of a blade or other end effector 162 of the vacuum robot 110 may be controlled by displacing the robot using a lift mechanism 252. In the embodiment depicted in FIG. 2, the lift mechanism 252 is coupled to the bottom of the chamber body 200 or base of the system 100 by a bracket (not shown). A second end of the lift mechanism 252 the base 160 of the vacuum robot 110, or as shown in the embodiment of FIG. 2, a cylinder 208 disposed between the robot base 160 and the lift mechanism 252. As utilized herein, the cylinder 208 is to be considered part of the robot base 160. The end effector 162 of the vacuum robot 110 is displaced vertically as the lift mechanism 252 is controllably positions (i.e., moves) the robot base 160 within the interior volume 210 of the chamber body 200. The lift mechanism 252 may be a hydraulic or pneumatic cylinder, lead or power screw, stepper or servo motor, or other device suitable for controlling the vertical position of the robot 210.

The rolling diaphragm 180 prevents leakage between the chamber body 200 and the vacuum robot 110 through the aperture 214. The rolling diaphragm 180 is sized such that an outer loop 270 of the diaphragm 180 is circumscribed and radially supported by an inner diameter 218 of the extension 216 through which the vacuum robot 110 extends. Thus, the pressure against the outer loop 270 is borne by the extension 216 and not the material of the diaphragm. The cylindrical inner diameter 218 is sufficiently long enough to support the outer loop 270 of the rolling diaphragm 180 through the complete range of motion of the diaphragm 180. The inner loop 272 of the rolling diaphragm 180 is supported by the cylinder 208 or base 160 of the vacuum robot 110. In the embodiment depicted in FIG. 2, the pressure against the inner loop 272 is borne by the outer surface of the cylinder 208 and not the material of the diaphragm.

In the embodiment depicted in FIG. 2, the rolling diaphragm 180 includes a flexible tubular body 230 having a first end 222 and second end 224. An interior wall 232 of the body 230 is coated and/or fabricated from a flexible material that does not introduce particulate and/or chemical contamination into the interior volume 110 during use under vacuum conditions. In one embodiment, the rolling diaphragm 180 is fabricated from a suitable elastomer, which may include a fabric, backing or other strengthening feature.

In the embodiment depicted in FIG. 2, the first end 222 of the rolling diaphragm 180 is coupled to the extension 216 while the second end 224 of the rolling diaphragm 180 is coupled to the vacuum robot 110. The first end 222 of the rolling diaphragm 180 generally has a diameter greater than the second end 224 so that the first end 222 may be easily moved relative to the second end 224, thereby defining in the inner and outer loops 272, 270.

Each of the first and second ends 222, 224 of the rolling diaphragm 180 terminate in a flange 274. The flange 274 has a ring shape and includes a plurality of mounting holes 276 arranged on a bolt circle. Annular clamp blocks 280 are utilized to sealingly compress the flanges 274 respectively against the extension 216 and cylinder 208. The clamp block 280 includes holes 284 through which fasteners 282 are passed. The holes 284 formed in the block 280 may have a counterbore to accommodate the heads of the fasteners 282. The fasteners 282 pass through the holes 276 of the diaphragm and engage threaded holes 286 respectively formed in the extension 216 and cylinder 208. Thus, tightening the fasteners 282 sealingly compress the flanges 274 to prove a vacuum seal. Optionally, as shown in FIG. 3, the flanges 274 may include one or more ribs 300 extending therefrom to enhance sealing between the diaphragm and adjacent component.

Beneficially, the use of the rolling diaphragm 180 eliminates the need for expensive bellows and lip seals, and contributes to a cleaner vacuum environment. Moreover, the use of the rolling diaphragm 180 eliminates the need for strict dimensional tolerances, thereby reducing the cost of the processing system.

FIG. 4 depicts another embodiment of a transfer chamber 106 having at least two rolling diaphragms (also referred to herein as a rolling diaphragm assembly 400) sealing the chamber body 200 to the vacuum robot 110. In the embodiment depicted in FIG. 4, the rolling diaphragm assembly 400 includes an inner rolling diaphragm 402 and an outer rolling diaphragm 404. The inner rolling diaphragm 402 is configured to provide a seal between the chamber body 200 and the vacuum robot 110. As an interior wall 406 of the inner rolling diaphragm 402 is exposed to the interior volume 210 of the chamber body 200, the interior wall 406 fabricated and/or coated with a material as described above.

The outer rolling diaphragm 404 is disposed over the inner rolling diaphragm 402 to provide a redundant chamber seal. The material utilized for the outer rolling diaphragm 404 may be selected from a wider range of materials as it is isolated from the substrate by the inner rolling diaphragm 402.

An interstitial space 408 defined between the inner and outer rolling diaphragms 402, 404 may be maintained at a pressure greater than a pressure of the interior volume 210, but less than a pressure of the ambient environment outside the transfer chamber 106. This staged pressure drop across the diaphragm assembly 400 results in a smaller pressure differential across each rolling diaphragm 402, 404, thereby allowing the diaphragms 402, 404 to be designed with thinner walls and from more flexible materials because of the reduced the pressure requirements, which further reduces size and cost of the rolling diaphragm. If additional rolling diaphragms are utilized, the interstitial space between each pair of diaphragms may be maintained at a pressure less than a pressure inward of the diaphragm pair but greater than a pressure outward of the diaphragm pair to minimize the pressure differential across each diaphragm.

Referring additionally to FIG. 5, an annular spacer block 444 is disposed between the first ends 422 of the first and second rolling diaphragms 402, 404. The spacer block 444 includes a vacuum port 446 formed therethrough. The vacuum port 446 is coupled to a vacuum source 448 by a passage 450. The vacuum source 448 may be utilized to provide a vacuum in the interstitial space 408 defined between the first and second rolling diaphragms 402, 404 such that the pressure is staged across the diaphragm assembly 400. For example, the pressure within the transfer chamber 106 may be on the order of 7-10 Torr, while the pressure in the interstitial space 408 is greater than the pressure within the processing chamber 106 but less than the pressure outside the second rolling diaphragm 404, for example between about 300-450 Torr.

A clamp block 280 is utilized to secure the first end 222 of the rolling diaphragms 402, 404 and spacer block 444 to the extension 216. The clamp block 280 and spacer block 444 includes a plurality through holes 284, 484 equally spaced about a bolt circle. The through holes 284 may include a counter bore to accept the head of a fastener 486 which engages a threaded hole 286 formed in the bottom surface of the extension 216. The rolling diaphragms 402, 404 each have holes 276 that align with the holes 284, 484, 286. The fasteners 282, when tightened, sealingly clamp the rolling diaphragms 402, 404 between their adjacent components.

Another clamp block 280 is utilized to secure the second end 224 of the rolling diaphragms 402, 404 and a second annular spacer block 440 to the cylinder 208. The spacer block 440 includes a plurality through holes 484 equally spaced about a bolt circle. The spacer block 440 does not require a passage to facilitate control of the pressure within the interstitial space 408 between the diaphragms 402, 404. A fastener 486 passes through the holes 284, 484, and 276 and engages a threaded hole 286 formed in the bottom surface of the cylinder 208. The fasteners 282, when tightened, sealingly clamp the second ends 242 of the rolling diaphragms 402, 404 between their adjacent components.

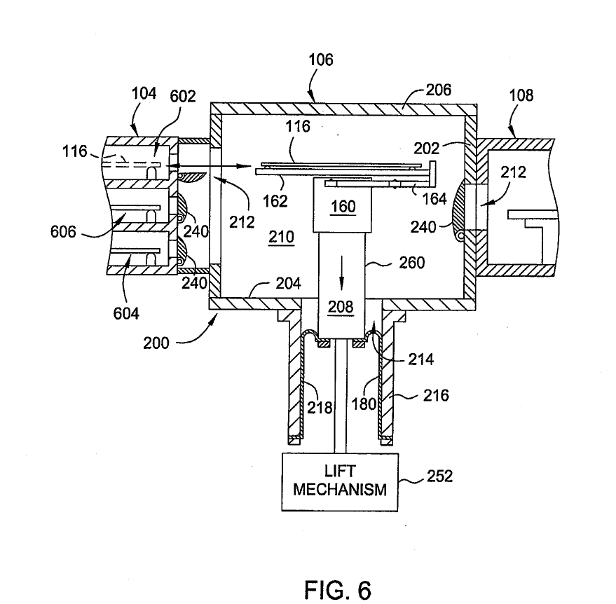

An exemplary description of one mode of operation of transfer chamber 106 is now provided. As shown in FIG. 6, the end effector 162 is elevated to align with an upper slot 602 of the load lock chamber 104 so that a substrate 116 may be retrieved from the load lock chamber 104. After the end effector 162 and substrate 116 are moved into the transfer chamber 106, the vacuum robot 110 rotates linkage to align the substrate with a selected processing chamber 108, and the end effector 162 is extended to delivery the substrate 116 to the selected processing chamber 108. In the sequence described above, the elevation of the end effector 162 may be required to change in elevation using the lift mechanism 252. After the substrate has been processed, typically with additional processing performed in at least one other processing chamber, the vacuum robot 110 retrieves the substrate 116 from the processing chamber and transfers the substrate to a lower slot 604 of the load lock chamber, changing the elevation of the end effector 162 (if required). At any point in this sequence, the substrate 116 may be deposited in the middle slot 606 of the load lock chamber 104 for heating, queuing or other reason.

Each change in the elevation of the end effector 162 requires the rolling diaphragm 180 to roll and unroll on the surfaces of the extension 216 and base 260 as described in the sequence above and illustrated with reference to FIGS. 2 and 6. The surfaces of the extension 216 and cylinder 208 generally provide the rolling diaphragm 180 a backing that assists in withstanding the pressure differential between the interior volume 210 and the environment outside the transfer chamber 106. In embodiments wherein two or more rolling diaphragms are utilized, such as shown in FIG. 4, a pressure gradient may be maintained across the rolling diaphragms by maintaining the interstitial space defined between at least two diaphragms at a pressure greater than the pressure within the transfer chamber but less than the pressure outside the chamber.

Thus, a transfer chamber having one or more rolling diaphragms disposed between the transfer chamber and a vacuum robot disposed in the transfer chamber. Beneficially, the use of one or more rolling diaphragms provides a clean vacuum environment and eliminates the need for expensive bellows and precision machined components. Moreover, the need for precision alignment required with the use of lip seals is also eliminated. Furthermore, in embodiments wherein multiple rolling diaphragms are utilized, a staged pressure drop may be maintain across the diaphragms which for thinner diaphragm walls and more flexible materials because of the reduced the pressure requirements. These benefits provide desirable cost savings, ease of assembly and ease of service. Additionally, the large range of vertical robot motion enabled by the use of a rolling diaphragm removes design constraints from other system components, such as the load lock chamber, which facilitates more robust system efficiency, throughput and cost of ownership management.

While the foregoing is directed to the preferred embodiment of the present invention, other and further embodiments of the invention may be devised without departing from the basic scope thereof. The scope of the invention is determined by the claims which follow.

1. An apparatus for transfer of large area substrates under vacuum, comprising:
a vacuum chamber body having sidewalls and a bottom;
a lift mechanism;
a robot substantially disposed in an interior volume of the chamber body and coupled to the lift mechanism, wherein the lift mechanism selectively controls the elevation of the robot within the interior volume; and
one or more rolling diaphragms providing a seal between the robot and the bottom of the chamber body.

2. The apparatus of claim 1, wherein the one or more rolling diaphragms further comprises:
a first rolling diaphragm; and
a second rolling diaphragm disposed over the first rolling diaphragm and creating a redundant seal.

3. The apparatus of claim 2 further comprising:
a spacer disposed between the first and second rolling diaphragms; and
a vacuum port formed through the spacer and fluidly coupled to an interstitial volume trapped between the first and second rolling diaphragms.

4. The apparatus of claim 1 further comprising:
at least two vertically offset access ports formed through at least one side wall of the chamber body.

5. The apparatus of claim 1, wherein the lift mechanism is configured to provide the robot with a vertical range of motion of at least 500 mm.

6. The apparatus of claim 1, wherein the rolling diaphragm further comprise:
an annular sealing flange having a plurality of holes formed therethrough; and
an annular rib extending from the flange inward of the holes.

7. An apparatus for transfer of large area substrates under vacuum, comprising:
a vacuum chamber body having sidewalls and a bottom, the sidewalls having a plurality of sealable substrate transfer ports formed therethrough;
a lift mechanism;
a robot substantially disposed in the interior volume of the chamber body and coupled to the lift mechanism, wherein the lift mechanism selectively controls the elevation of the robot within the interior volume;
a first rolling diaphragm and a second rolling diaphragm arranged in series and having an interstitial volume defined therebetween, the first and second rolling diaphragms providing a seal that facilitates change in the elevation of the robot without vacuum leakage; and
a spacer sealed to the first and second rolling diaphragms, the spacer having a passage formed therethrough and communicating with the interstitial volume, the passage terminating in a port configured to accept a fitting for coupling to a vacuum source.

8. The apparatus of claim 7 further comprising:
a load lock chamber having at least two vertically stacked substrate storage slots accessible by the robot through at least one access port of the chamber body.

9. The apparatus of claim 7 further comprising:
a load lock chamber having at least three vertically stacked substrate storage slots accessible by the robot through at least one access port of the chamber body.

10. The apparatus of claim 9, wherein the load lock chamber further comprises:
a first internal region having a first slot of the at least three substrate storage slots defined therein; and
a second internal region having a second slot of the at least three substrate storage slots defined therein, wherein the first and second slots are fluidly isolatable when the load lock chamber is in operation.

11. The apparatus of claim 7, wherein the lift mechanism is configured to provide the robot with a vertical range of motion of at least 500 mm.

12. A method for transferring a large area substrate, comprising:
providing a transfer chamber having a robot disposed therein, the transfer chamber coupled to a load lock chamber and at least one processing chamber, the robot having an elevation selectable by a mechanism, the robot sealed to the transfer chamber by one or more rolling diaphragms;
robotically transferring a substrate from at least one of the processing chamber or load lock chamber to the transfer chamber;
adjusting the elevation of the of the substrate within the transfer chamber in a manner that causes a first end of the rolling diaphragm to move relative to a second end; and
robotically transferring the substrate from the transfer chamber to at least one of the processing chamber or load lock chamber.

13. The method of claim 12, wherein the at least one rolling diaphragm further comprises:
a first rolling diaphragm; and
a second rolling diaphragm disposed over the first rolling diaphragm and creating a redundant seal.

14. The method of claim 13 further comprising:
maintaining an interstitial space defined between the first and second rolling diaphragms at a pressure greater than a pressure inside the transfer chamber but less than an ambient pressure outside the transfer chamber.
